(19) United States
(12) Patent Application Publication
(10) Pub. No.: US 2007/0152653 A1
(43) Pub. Date: Jul. 5, 2007

(54) System and method for reducing common-mode interference in differential or single-ended signals

(75) Inventor: Dale Roche, Ventura, CA (US)

Correspondence Address: Ira M. Siegel;LAW OFFICES OF IRA M. SIEGEL, Suite 970, 433 N. Camden Drive, Beverly Hills, CA, 90210, US

(73) Assignee: Jensen Transformers, Inc.

(21) Appl. No.: 11/321,503

(22) Filed: Dec. 29, 2005

(51) Int. Cl. G01R 13/04

(52) U.S. Cl. 324/100

(57) ABSTRACT

The invention includes input terminals receiving electrical signals from a driver, output terminals delivering the electrical signals to a receiver, and a set of conductors connected between the input and output terminals. Also included are a coupler, its input electrically isolated from its output which includes a first segment of the plurality of conductors, a common-mode current sensor, its input including a second segment of the set of conductors, which sensor outputs a sensor signal corresponding to the common-mode current, and an amplifier having its input connected to the sensor's output, which amplifier delivers a first voltage to the coupler's input. The coupler delivers to the set of conductors a second voltage corresponding to the first voltage, which second voltage is in phase and approximately the same magnitude as the voltage creating the common-mode interference current, thereby reducing the common-mode interference current.

### BACKGROUND OF THE INVENTION

1. Field of the Invention

The invention relates to the reduction of common-mode interference in electric circuits.

2. Description of the Prior Art

When electrical signals are transmitted from one piece of equipment to another piece of equipment using wires, the signals may become contaminated with interference (sometimes referred to as “noise”) due to the fact that additional unwanted currents may also flow in the signal conductors because of actual small voltage differences between the zero volt (or“ground”) references of the two pieces of equipment. The voltage difference between the ground references of two pieces of equipment causes what is known as a “common-mode current” or “common-mode interference current” to flow in the conductors connected between the two pieces of equipment. This common-mode current gives rise to what is often referred to as “common-mode interference,” which obviously degrades the intended signal. This problem is especially troublesome in (but not limited to) audio, video and instrumentation applications.

Prior art solutions for the common-mode interference problem include isolation transformers in a signal cable or in a power line, differential amplifiers in the signal cable, and common-mode chokes (commonly referred to as “hum-buckers”) in the signal cable. No prior art device has used the invented elements and structure described herein.

### SUMMARY OF THE INVENTION

The invention takes advantage of the fact that the unwanted common-mode interference signal flows in the same direction in all pertinent conductors, whereas the desired current flows in equal and opposite directions in the pertinent conductors. By utilizing a current sensing device that responds only to the common-mode current in the conductors, an amplifier and coupling device (such as a transformer) can be used to reduce the common-mode current (and thus, the interference) to an arbitrarily low value.

The invention includes input terminals receiving electrical signals from a driving piece of equipment, output terminals delivering the electrical signals to a receiving piece of equipment, and a set of conductors connected between the input and output terminals. Also included are a coupler having its input electrically isolated from its output which includes a first segment of the plurality of conductors, a common-mode current sensor having an input which includes a second segment of the plurality of conductors, which sensor outputs a sensor signal corresponding to the common-mode current, and an amplifier having its input connected to the current sensor's output, which amplifier delivers a first voltage to the coupler's input. The coupler delivers to the set of conductors a second voltage corresponding to the first voltage, which second voltage is in phase and approximately the same magnitude as the voltage creating the common-mode interference current. The common-mode interference current is thus significantly reduced.

In another embodiment, the invention may be inserted in the line providing power to either the driving piece of equipment or the receiving piece of equipment.

### Brief Description of the Drawings

FIG. 1 is a schematic drawing of the electrical circuit of the invention inserted between two pieces of equipment.

FIG. 2 is a schematic drawing of the preferred embodiment of the invention inserted between two pieces of equipment.

FIG. 3 is a schematic drawing of the invention inserted between one piece of equipment and a power source for that piece of equipment.

### Detailed Description of the Invention

The preferred embodiments of the subject invention are illustrated in the attached drawings which are referred to herein. The same reference numeral will be used to identify identical elements throughout the drawings.

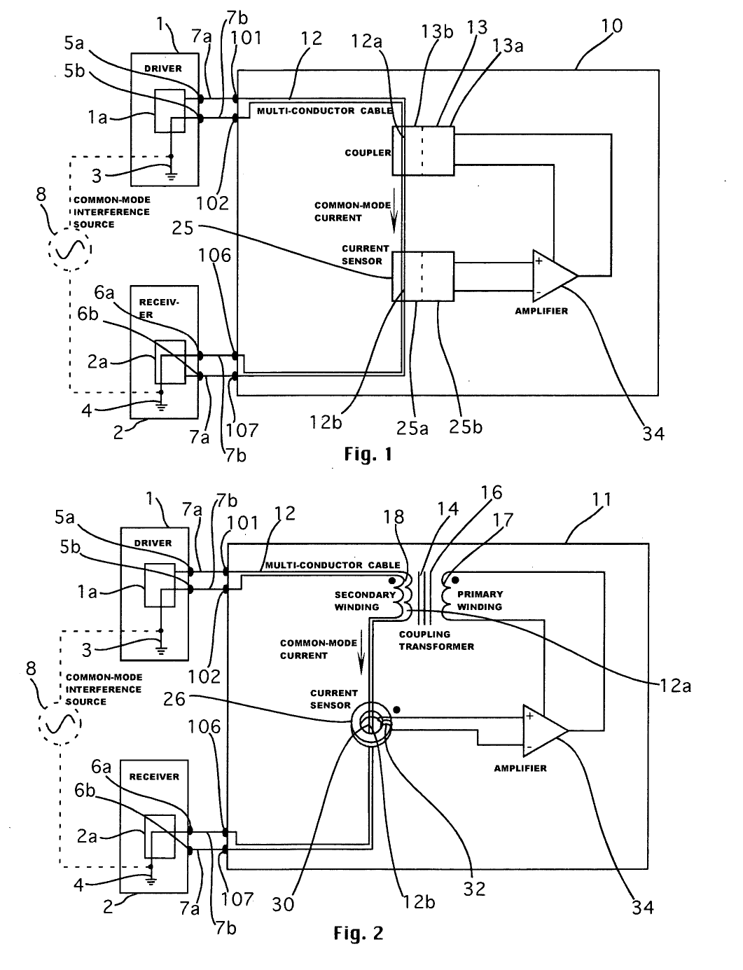

An example of the present invention is circuit 10 shown in FIG. 1. FIG. 2 illustrates circuit 11 of the preferred embodiment of the invention. For purposes of convenience only, the invention will be referred to herein as a“hum canceller.” The hum canceller's input is attached by electrical conductors 7a/7b to the output of a first piece of equipment 1, which may be any of various signal sources including without limitation a CD player, FM tuner, VCR, computer, and industrial sensor. First piece of equipment 1 may be thought of as a signal source or driver. The hum canceller's output is connected by electrical conductors 7a/7b to the input of a second piece of equipment 2, which may be any of various devices including without limitation an audio amplifier, sound system mixer, a data processing device, and an instrumentation amplifier. Second piece of equipment 2 may be thought of as a signal receiving device or receiver.

The signal transport system between the first and second pieces of equipment (i.e., from and including driver 1's line driver 1a , through the output terminals 5a/5b of the driver and through the input terminals 6a/6b of the receiver 2 to and including the receiver's line receiver 2a, and including the electrical conductors 7a/7b and any other devices electrically connecting the first and second pieces of equipment to each other) is referred to as an“interface.”

Without the present invention, the output of the first piece of equipment would usually be connected directly to the input of the second piece of equipment at least by two electrical conductors (represented by conductors 7a/7b in FIGS. 1, 2 and 3). The invention is useful in many-applications including, but not limited to, sound systems, video systems, data systems, industrial control systems and instrumentation systems.

Many line drivers and line receivers are referred to as “unbalanced” because a signal conductor of the line driver or line receiver is connected to its respective driver or receiver's local zero volt reference point 3 (for the driver or 4 for the receiver), often referred as “ground.” If either or both of the line driver or line receiver is unbalanced, then the entire interface is unbalanced.

In balanced interface systems, no signal conductor of either of the line driver and the line receiver is connected to any ground. Often a third conductor, which is not a signal conductor, is connected between the first and second pieces of equipment for shielding purposes in a balanced interface. This third conductor is connected to a ground at either the driver or receiver, or sometimes at both. (This third conductor is not shown in the drawings.)

Since the grounds of the driver and receiver are independent of each other, a voltage difference (often referred to as a “ground voltage difference”) exists between them (and concomitantly across the interface) even if the first piece of equipment (the driver) and the second piece of equipment (the receiver) are in close proximity to each other. It is a fact of life that voltage differences always exist between any two “ground” points in a system. It is not necessary to describe how the voltage differences arise to explain how this invention reduces their effects. Since the voltage difference between “ground” points exists in unbalanced and balanced systems, and since such voltage difference induces a common-mode interference current in both unbalanced and balanced systems, it is only necessary to illustrate the invention in connection with an unbalanced system to show how the invention works.

The voltage difference between the grounds of the driver and receiver is represented in FIGS. 1 and 2 by voltage generator 8 connected between the local respective zero volt reference points of the driver and receiver. Voltage generator 8 and the electrical connections from it to the grounds of the driver and receiver are shown in dashed lines because, while the voltage really exists, there are no specific corresponding generator and connecting wires which actually exist. When the driver and receiver are directly connected to each other by electrical conductors (often a pair of signal conductors 7a/7b in a signal cable for an unbalanced system and three conductors (two signal conductors and one shield) in a signal cable for a balanced system), a current, due to the ground voltage difference represented by voltage generator 8, would flow through the interface (including the signal conductors (and, in a balanced system, the shield as well)) and, consequently, add noise to the signal which would be sensed at the receiver. Since this current flows in the same direction in all the electrical conductors, it is known as the“common-mode current.”

Circuit 10 (as shown in FIG. 1, and circuit 11 as shown in FIG. 2) is connected in series between the driver and the receiver. Essentially, the input of the invented circuit 10 (circuit 11 in FIG. 2) is electrically connected to the output of the driver and the output of the invented circuit is electrically connected to the input of the receiver.

The invented hum canceller 10 as shown in FIG. 1 (11 as shown in FIG. 2) includes a set of a plurality of conductors 12 (which set of conductors is often referred to as a “cable”), which would typically be two signal conductors in the case of an unbalanced system (and may be two signal conductors plus a third conductor, acting as a shield, in the case of a balanced system). One end of the set of conductors is connected to the input terminals 101/102 of the hum canceller, and the other end is connected to the output terminals 106/107 of the hum canceller. (In a balanced system, there would be a third input terminal and a third output terminal for the shield).

The invented hum canceller includes a coupler 13 as shown in FIG. 1, the input 13a of which is typically electrically isolated from its output 13b . The output 13b of the coupler includes a first segment 12a of the set of conductors (even if none of the other parts of the coupler physically contact the set of conductors). The input 13a of the coupler is connected to the output of amplifier 34. (Amplifier 34 is discussed further below.)

In the preferred embodiment, shown in FIG. 2, the coupler is a coupling transformer 14 having primary and secondary windings around a magnetic core 16. The core 16 would typically be a ferrous core. The primary winding 17 of the coupling transformer is an electrical conductor wrapped around core 16 and having its ends connected to the output of amplifier 34.

The secondary winding 18 of the coupling transformer is a multiple conductor winding formed by the above-mentioned first segment 12a of the set of conductors.

As indicated above, in one embodiment of the invention, the secondary winding 18 of the coupling transformer is a multiple conductor winding formed by a segment of the cable 12. In another embodiment, the secondary winding 18 may be a separate set of conductors with one end connected to the portion of cable 12 which is connected to the input terminals of the hum canceller and its other end connected to the portion of cable 12 which is ultimately connected to output terminals of the hum canceller (as illustrated in FIG. 1 and, in FIG. 2, through the current sensor to terminals 106/107). Regardless of whether secondary winding 18 is part of a continuous set of wires forming the entirety of cable 12 or is a separate set of wires which is part of an “off the shelf” transformer, which set of wires is electrically connected to the other portions of cable 12, the secondary winding of the coupling transformer is considered to be the first segment 12a of the set of conductors 12.

The hum canceller also includes a common-mode current sensor 25 arranged to sense the common-mode current in the set of conductors. In typical practice, the sensor's input 25a of the sensor will be electrically isolated from the sensor's output 25b . The input 25a of the sensor includes a second segment 12b of the set of conductors 12 (even if none of the other parts of the sensor physically contact cable 12). The output 25b is connected to the input of amplifier 34.

In the preferred embodiment, the current sensor is disposed adjacent the set of conductors. In particular, as shown in FIG. 2, the current sensor is a current sensing transformer 26 with its primary winding 30 being the second segment 12b of the set of conductors. In the version illustrated in FIG. 2, the current sensor has a toroidal ferrous core and the primary winding 30 is second segment 12b passing through the core. In another embodiment, the primary winding 30 of the sensor may be a separate set of conductors with one end connected to the portion of cable 12 which is ultimately connected to the hum canceller's input terminals (as illustrated in FIG. 1 and, in FIG. 2, through the coupler to terminals 101/102 ) and its-other end connected to the portion of cable 12 which is ultimately connected to output terminals of the hum canceller (terminals 106/107 in FIGS. 1 and 2). Regardless of whether primary winding 30 is part of a continuous set of wires forming the entirety of cable 12 or is a separate set of wires which is part of an “off the shelf” current sensing transformer, which set of wires is electrically connected to the other portions of cable 12, the primary winding of the current sensing transformer is considered to be the second segment 12b of the set of conductors 12.

The output 25b of the current sensor 25 as shown in FIG. 1 is applied to the input of amplifier 34. In the preferred embodiment, shown in FIG. 2, secondary winding 32 of the current sensor is an electrical conductor wrapped around the toroidal core. The ends of the secondary winding are the output of the sensor. These ends are connected to the input of amplifier 34.

The output of the current sensor (in the preferred embodiment the output from its secondary winding) is a sensor output signal, here a voltage corresponding to the common-mode current flowing in the set of conductors 12, which is the same common-mode current flowing in the secondary winding of the coupling transformer. The current sensor does not respond to the differential signal current because the differential signal current flows in equal and opposite directions in the signal conductors.

Amplifier 34 is preferably a high gain voltage amplifier. The output of amplifier 34 drives the input 13a of coupler 13 as shown in FIG. 1 (primary winding 17 of coupling transformer 14 in the preferred embodiment shown in FIG. 2). As a result of the voltage across input 13a of the coupler (across the primary winding 17 of the coupling transformer 14 shown in FIG. 2), a voltage is induced into the coupler's output 13b (the coupling transformer 14's secondary winding 18 in the preferred embodiment), which voltage is in phase with the voltage arising from the ground voltage difference between the driver and receiver. (The dots shown at one end of each transformer winding in FIG. 2 indicate points of same instantaneous polarity.) By selecting the gain of amplifier 34 appropriately, the common-mode current can be reduced to, and maintained at, an insignificant level. The output of the hum canceller will be the signal intended to be output by the driver and delivered to the receiver, accompanied by a much lower common-mode current than if the hum canceller were not part of the circuit.

The following discussion, with particular reference to FIG. 2, will further explain the operation of the hum canceller. The following simplifying assumptions about the various circuit elements are made in order to describe the operation of the invention:
(i) The common-mode interference source 8 is generating a 1 volt AC signal.
(ii) The effective resistance of all the electrical conductors from the output of the driver, through the hum canceller, to the receiver is 1 ohm.
(iii) The sensitivity of the current sensor is 1 volt per ampere.
(iv) The voltage gain of amplifier 34 is 1,000.
(v) The turns ratio of coupling transformer 14 is 1 to 1.

The 1 volt interference signal of the common-mode interference source would normally result in a 1 ampere common-mode current flowing through the 1 ohm two-conductor signal cable (by Ohm's law 1 volt÷1 ohm=1 amp).

If a 1 volt canceling signal were applied to the primary winding 17 of coupling transformer 14, it would result in a 1 volt canceling signal across secondary winding 18, since the coupling transformer turns ratio is 1 to 1. This would reduce the common-mode current in the interface to zero because the induced canceling voltage in both conductors of the two-conductor secondary winding would be virtually identical to the interference voltage generated by the common-mode interference source.

As noted above, amplifier 34 would be the source of the 1 volt canceling signal across the coupling transformer's primary winding. In this example, a 1 volt canceling signal at the amplifier output is required to reduce the common-mode current in the two-conductor cable to zero. With the amplifier's gain being 1000, only a 1 mV signal is needed at its input to generate the 1 volt canceling signal.

Since the current sensor has a sensitivity of 1 volt per ampere, only a 1 mA current would be required to generate the 1 mV input signal needed by the amplifier. This means that the feedback loop will stabilize at a point where the common-mode current equals approximately 1 mA.

Thus, the common-mode current in the interface is reduced from 1 ampere to 1 mA. This is a reduction factor of 1,000 (or 60db) in the common-mode current (and thus, the interference). Improved reduction can be made by increasing the amplifier's gain. In practice, the gain of the amplifier would be limited only by practical gain and stability issues relating to the particular amplifier, transformer and current sensor used.

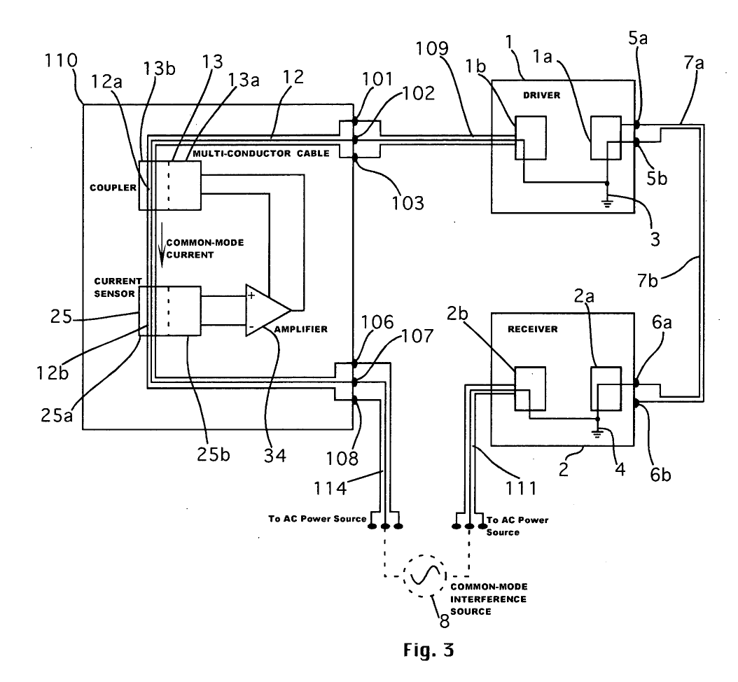

Another embodiment of the invention is shown in FIG. 3. The hum canceller is connected in series between one of the first and second pieces of equipment and the source of power for that piece of equipment.

As shown in FIG. 3, driver 1 and receiver 2 have power lines 109 and 111, respectively, having one end connected to their internal power supplies 1b and 2b, respectively. Each of the power lines 109 and 111 include a two “hot” conductors and a neutral conductor, the last of which is electrically connected to the respective internal reference points 3 and 4 of the driver and receiver. Without the present invention, the other end of each power line would be connected to the source of power for the piece of equipment. In the embodiment shown in FIG. 3, the source of power is an AC power source.

In this embodiment, the other end of one of the pieces of equipment, here the driver, is connected to the hum canceller. Hum canceller 110 shown in FIG. 3, is the same as hum canceller 10 shown in FIG. 1, except that the hum canceller 110 has three input terminals 101, 102 and 103 and three output terminals 106, 107 and 108, and cable 12 has three conductors, two of which corresponds to the hot conductors of the power lines and the third corresponds to the neutral conductor. The output terminals of hum canceller 110 are connected by power line 114 to the power source.

In FIG. 3, the voltage difference between the grounds of the driver and receiver is represented by voltage generator 8 connected between the neutral conductors of the power lines.

Hum canceller 110 works the same way as hum canceller 10 and results in the significant reduction of common-mode current (and common-mode interference) in the interface.

A preferred version of this hum canceller may have the same elements as the hum canceller 11 illustrated in FIG. 2. The elements of hum canceller of FIG. 3 would have a higher power capacity than the hum canceller's shown in FIGS. 2 and 3.

The invention also includes a method for reducing common-mode interference in a signal interface. That method includes the following steps:

1. Applying a feed-back circuit to a set of conductors carrying common-mode interference current, which feed-back circuit includes a current sensor, an amplifier and a coupler;

2. Having the current sensor develop a sensor output signal which corresponds substantially only to common-mode interference current in the set of conductors;

3. Having the amplifier apply an amplified sensor output signal to the coupler; and

4. Having the coupler induce in the set of conductors a voltage which is in phase with and approximately the same magnitude as the voltage creating the common-mode interference current.

It will be understood that various changes of the details, materials, steps, arrangement of parts and uses which have been herein described and illustrated in order to explain the nature of the invention will occur to and may be made by those skilled in the art, and such changes are intended to be included within the scope of this invention.

I claim the following:

1. A circuit for reducing interference in a signal interface, said circuit comprising:
(a) a plurality of input terminals and a plurality of output terminals;
(b) a plurality of conductors connected between the input and output terminals;
(c) a coupler having a coupler input and a coupler output, wherein said coupler output comprises a first segment of said plurality of conductors, said coupler output being electrically isolated from said coupler input, wherein said coupler delivers a second voltage to said plurality of conductors which corresponds to a first voltage at said coupler's input;
(d) a common-mode current sensor having a sensor input, which sensor input comprises a second segment of said plurality of conductors, and a sensor output, said common-mode sensor being responsive to common-mode current flowing in the plurality of conductors, said common-mode current sensor delivering from its output a sensor output signal which corresponds to the common-mode current flowing in said plurality of conductors; and
(e) an amplifier having an amplifier input and an amplifier output, with the amplifier input connected to the sensor output and the amplifier output connected to the coupler input.

2. The interference reducing circuit of claim 1 wherein said coupler is a coupling transformer having a primary winding and a secondary winding and wherein said secondary winding of said coupling transformer is said first segment of said plurality of conductors.

3. The interference reducing circuit of claim 2 wherein said current sensor is a current sensing transformer having a primary winding and a secondary winding and wherein the primary winding of said current sensor is said second segment of said plurality of conductors.

4. The interference reducing circuit of claim 3 wherein said plurality of conductors includes a shield conductor.

5. A method for reducing common-mode interference in a signal interface, said method including the following steps:
(a) applying a feed-back circuit to a set of conductors carrying common-mode interference current, which feed-back circuit includes a current sensor, an amplifier and a coupler;
(b) having the current sensor develop a sensor output signal which corresponds substantially only to common-mode interference current in the set of conductors;
(c) having the amplifier apply an amplified sensor output signal to the coupler; and
(d) having the coupler induce in the set of conductors a voltage which is in phase with and approximately the same magnitude as the voltage creating the common-mode interference current.
